(19) United States
(12) Patent Application Publication
(10) Pub. No.: US 2015/0319849 A1
(43) Pub. Date: Nov. 5, 2015

(54) COMPONENT FIXING STRUCTURE, CIRCUIT BOARD, AND DISPLAY PANEL

(71) Applicant: SHARP KABUSHIKI KAISHA, Osaka (JP)

(72) Inventors: Yukio SHIMIZU, Osaka (JP); Motoji SHIOTA, Osaka (JP); Hiroki MIYAZAKI, Osaka (JP); Hiroki NAKAHAMA, Osaka (JP); Seiji MURAOKA, Osaka (JP); Takeshi HORIGUCHI, Osaka (JP)

(73) Assignee: SHARP KABUSHIKI KAISHA, Osaka (JP)

(21) Appl. No.: 14/650,416

(22) PCT Filed: Dec. 9, 2013
(86) PCT No.: PCT/JP2013/082909

§ 371 Date: Jun. 8, 2015

(30) Foreign Application Priority Data
Dec. 12, 2012 (JP) 2012-270986

(51) Int. Cl. H05K 1/02; H05K 3/40; H05K 3/32

(52) U.S. Cl. CPC H05K 1/0274; H05K 3/323; H05K 3/4007; H05K 2201/10128; H05K 2201/0108

(57) ABSTRACT

The present invention provides a component securing structure that forms a wiring unit on a TFT glass substrate that is capable of transmitting UV light. A component, such as a driver IC and/or an FPC, is electrically connected to the wiring unit and is secured to the TFT glass substrate by a UV-curable ACF. An opening for transmitting UV light is formed in a light shielding layer of the wiring unit. UV light irradiated from the back side of the TFT glass substrate passes through the opening and directly irradiates the UV-curable ACF.

### TECHNICAL FIELD

The present invention relates to a component securing structure, a circuit board on which the component securing structure is used, and a display panel that includes the circuit board as a constituent element.

### BACKGROUND ART

A display panel like a liquid crystal display panel or an organic EL display panel is modularized by combining components, such as a driver IC for the driving thereof and a flexible printed circuit (FPC). In the modularization of the display panel, a technique for electrically connecting and physically securing a component to an electrode section formed on the surface of the display panel substrate using an anisotropic conductive film (the designation “ACF” will be used in the present specification and claims hereinafter) is generally employed. Examples of this can be seen in Patent Documents 1 and 2.

In a method of manufacturing a liquid crystal display device disclosed in Patent Document 1, an ACF, having as an adhesive a resin that is cured by both ultraviolet rays (UV light) and heat, is used when connecting either a tape carrier package (TCP) or a flexible printed circuit to a liquid crystal display element. After positioning the connection electrode of the liquid crystal display element and the electrode of either the TCP or the flexible printed circuit, and applying pressure, UV light is irradiated for a prescribed time and at a prescribed intensity onto the ACF adhesive layer from the liquid crystal display element side. In accordance with this, the ACF adhesive in an area that is not shielded from the light by the liquid crystal display element connection electrode achieves a high degree of hardness via a photocuring reaction. Next, pressure and heat are applied to either the TCP or the flexible printed circuit to achieve bonding by pressure. Because the flow of a conductive material is suppressed by the cured adhesive at this time, electricity is reliably conducted between the electrode of either the TCP or the flexible printed circuit and the connection electrode of the liquid crystal display element.

In a manufacturing method of a semiconductor element disclosed in Patent Document 2, an ACF, which is cured using heat, is used when securing the semiconductor element to an array substrate. Prior to thermosetting the semiconductor element to the array substrate, a laser light is irradiated onto conductive particles in the ACF, which is held between a bump of the semiconductor element and a panel electrode, to melt the conductive particles. In accordance with this, a temporary connection is formed via the conductive particles between the bump and the panel electrode. Thereafter, an adhesive in the ACF is heated to a flowable state, and the semiconductor element is bonded to the array substrate by pressure. The connection between the bump and the panel electrode can be reliably maintained because the conductive particles held between the bump and the panel are not displaced.

### RELATED ART DOCUMENTS

### Patent Documents

Patent Document 1: Japanese Patent Application Laid-Open Publication No. 2000-105388

Patent Document 2: Japanese Patent Application Laid-Open Publication No. 2008-282978

### SUMMARY OF THE INVENTION

### Problems to be Solved by the Invention

In the method of manufacturing a liquid crystal display device disclosed in Patent Document 1, the problem is that ACF curing is performed using both UV light and heat, and the components and substrate are warped by the heat. In the method of manufacturing a semiconductor element disclosed in Patent Document 2, the problem is that ACF curing is performed using heat, and the components and substrate are warped by the heat in the same manner.

Furthermore, the recent trend in liquid crystal display panels is to reduce areas other than the display section as much as possible with the aim of making the frame narrower, and the distance between the display section and the driver IC, and the distance between the driver IC and the FPC have shrunk dramatically. When the distance shrinks like this, the heat for curing the ACF has various adverse effects. There occur phenomena such as display degradation and a reduction in the connection reliability of the driver IC and/or FPC, for example.

There have been advances in the development of UV-curable ACF in recent years, and when using a UV-curable ACF that is cured using UV light alone, component connections can be secured at relatively low temperatures. Therefore, the use of a UV-curable ACF is advantageous in that, in addition to less heat damage being done to components and substrates, manufacturing efficiency can also be enhanced since it is possible to reduce the time required to raise the temperature to a target temperature.

On the other hand, a UV-curable ACF also has the following disadvantages. In the case of the ACF disclosed in Patent Document 1, the ACF can be cured by heating at locations shielded from the light by the wiring unit (the term “wiring unit” is used in the present specification as a concept including both an electrode that electrically connects a component, and wiring that connects the electrodes), but a heat-based curing technique cannot be used with a UV-curable ACF. The light-shielded locations of the ACF are also somewhat cured by UV light that is reflectively transmitted inside the ACF, but this curing is inadequate, and the ACF has to be considered uncured.

An uncured ACF is not able to exhibit the intrinsic performance of the ACF, and this gives rise to all sorts of problems. These problems include a reduction in the adhesion between a component and the substrate, an increase in electrical resistance due to low cure shrinkage of the resin, and changes in moisture-absorption characteristics. An uncured ACF absorbs moisture more readily, thereby giving rise to defects such as an increase in electrical resistance brought on by the substrate corroding, absorbing moisture, and swelling. In order to realize highly reliable component mounting, curing must be done in excess of a prescribed reaction ratio over the entire area of the ACF. The prescribed reaction ratio differs in accordance with the type of ACF, but 80% or higher is the norm.

With the foregoing points in mind, when securing a component to a substrate using a UV-curable ACF, an object of the present invention is to provide a structure in which uncured UV-curable ACF is not left behind by enabling UV light to be directly irradiated onto the UV-curable ACF at a location shielded from the light by a wiring unit.

### Means for Solving the Problems

A component securing structure according to the present invention is formed as follows. In a component securing structure that forms a substrate capable of transmitting UV light and having a wiring unit formed thereon, the substrate electrically connecting a component thereon to the wiring unit and securing the component to the substrate with a UV-curable ACF, wherein an opening for transmitting UV light is formed in a light shielding layer of the wiring unit.

It is preferable that the component securing structure constituted as described above be formed as follows: one of the opening in one of the light shielding layer having a shape similar to that of the light shielding layer.

It is preferable that the component securing structure constituted as described above be formed as follows: a plurality of the openings being dispersed in one of the light shielding layer.

It is preferable that the component securing structure constituted as described above be formed as follows: the plurality of openings being arranged in a matrix.

It is preferable that the component securing structure constituted as described above be formed as follows: the light shielding layer and the opening being shapes each having a longitudinal direction, and the opening being parallelly arranged in such a way that the longitudinal direction of the opening itself coincides with the longitudinal direction of the light shielding layer.

It is preferable that the component securing structure constituted as described above be formed as follows: the light shielding layer and the opening being shapes each having a longitudinal direction, and the opening being parallelly arranged in such a way that the longitudinal direction of the opening itself intersects with the longitudinal direction of the light shielding layer.

Furthermore, the present invention is formed using a circuit board that includes the component securing structure.

Furthermore, the present invention is formed using a display panel that includes the circuit board as a constituent element.

### Effects of the Invention

According to the present invention, by forming an opening in the wiring unit for the transmission of UV light, the UV light is also irradiated onto the UV-curable ACF at locations where light is shielded by the wiring unit. This makes it possible to eliminate an ACF that remains uncured due to the non-irradiation of UV light, and to resolve defects that occur as a result of the ACF being uncured.

### BRIEF DESCRIPTION OF THE DRAWINGS

FIG. 1 is a plan view of a wiring unit structure according to Embodiment 1.

FIG. 2 is a cross-sectional view taken along the line A-A in FIG. 1.

FIG. 3 is a cross-sectional view taken along the line B-B in FIG. 1.

FIG. 4 is a plan view of a wiring unit structure according to Embodiment 2.

FIG. 5 is a cross-sectional view taken along the line A-A in FIG. 4.

FIG. 6 is a cross-sectional view taken along the line B-B in FIG. 4.

FIG. 7 is a plan view of a wiring unit structure according to Embodiment 3.

FIG. 8 is a cross-sectional view taken along the line A-A in FIG. 7.

FIG. 9 is a cross-sectional view taken along the line B1-B1 in FIG. 7.

FIG. 10 is a cross-sectional view taken along the line B2-B2 in FIG. 7.

FIG. 11 is a plan view of a wiring unit structure according to Embodiment 4.

FIG. 12 is a cross-sectional view taken along the line A1-A1 in FIG. 11.

FIG. 13 is a cross-sectional view taken along the line A2-A2 in FIG. 11.

FIG. 14 is a cross-sectional view taken along the line B-B in FIG. 11.

FIG. 15 is a schematic diagram showing an example of the configuration of a substrate on which components are secured.

FIG. 16 a schematic diagram showing a state in which components are secured to the substrate of FIG. 15.

FIG. 17 is a plan view of a wiring unit structure that does not implement the present invention.

FIG. 18 is a cross-sectional view taken along the line A-A in FIG. 17.

FIG. 19 is a cross-sectional view taken along the line B-B in FIG. 17.

### DETAILED DESCRIPTION OF EMBODIMENTS

FIG. 15 shows an example of the configuration of a circuit board where a component securing structure according to the present invention is applied. The circuit board shown as an example in FIG. 15 is a TFT glass substrate 1 of a liquid crystal display panel. Because the TFT glass substrate 1 is glass, the TFT glass substrate 1 is able to transmit UV light. In the explanation that follows, when reference is made to the top-bottom or left-right of the TFT glass substrate 1, it is assumed this reference specifies the top-bottom or left-right in FIG. 15.

A color filter panel is superimposed at a location toward the top of the TFT glass substrate 1 to form a display section 2. A chip on glass (COG) mounting section 3 and a film on glass (FOG) mounting section 4 are provided at locations outside of the display section 2, these locations being situated below the display section 2 on the TFT glass substrate 1. The FOG mounting section 4 is arranged at the lower edge of the TFT glass substrate 1. The COG mounting section 3 is arranged between the FOG mounting section 4 and the display section 2.

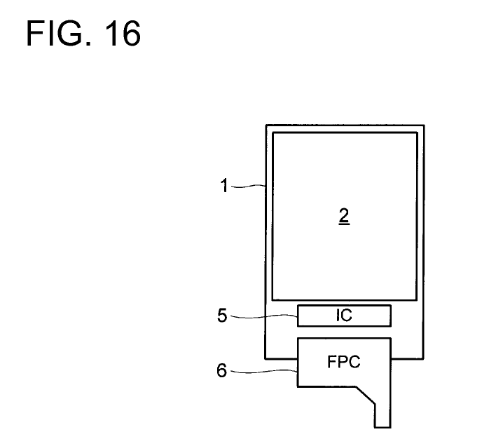

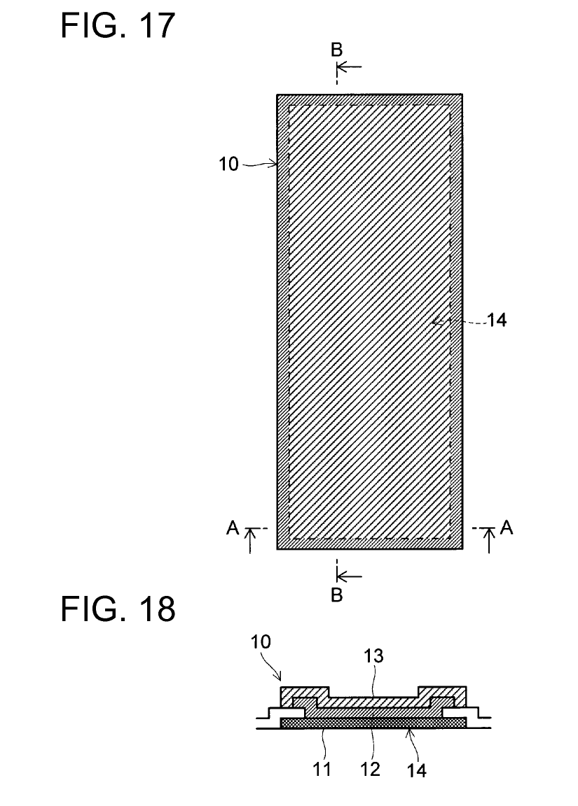

As shown in FIG. 16, a driver IC 5 is mounted to the COG mounting section 3, and an FPC 6 is mounted to the FOG mounting section 4. A UV-curable ACF (not shown) is used to mount the driver IC 5 and the FPC 6. The UV-curable ACF electrically connects a wiring unit included in the COG mounting section 3 with a bump on the driver IC 5, and a wiring unit included in the FOG mounting section 4 with a terminal portion of the FPC 6. In accordance with this, the driver IC 5 and the FPC 6 are secured to the TFT glass substrate 1. The UV-curable ACF is cured using UV light irradiated from the back side of the TFT glass substrate 1.

The COG mounting section 3 and the FOG mounting section 4 are both formed from a plurality of wiring units 10. The wiring unit 10 is formed from a metal having low electrical resistance, and because light does not pass through, the wiring unit 10 becomes a light shielding portion relative to the UV light. An individual wiring unit 10 is a quadrilateral shape, such as a rectangle and/or a square.

### Prior Art

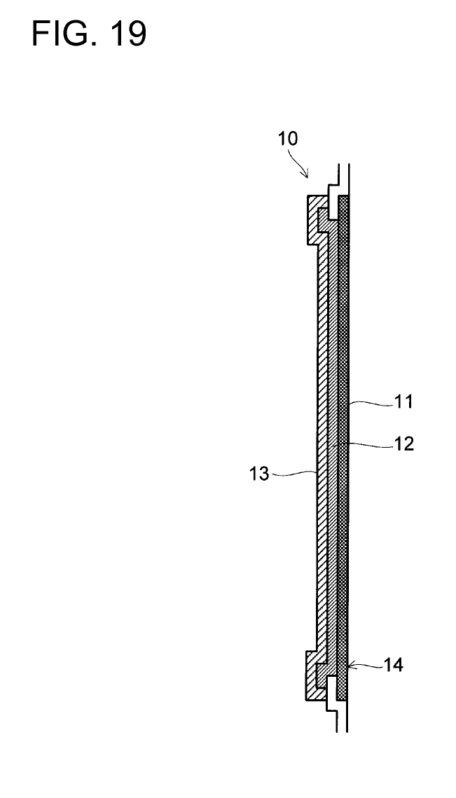

FIGS. 17 to 19 show the structure of a wiring unit 10 that does not implement the present invention, that is, a wiring unit 10 that corresponds to prior art. The wiring unit 10 forms a three-layer structure constituting two metal layers 11 and 12 laminated one on top of the other, and a transparent conductive film 13 laminated on top thereof. The metal layers 11 and 12 are formed from a low-resistance metal such as aluminum or copper. The transparent conductive film 13 is formed from indium tin oxide (ITO) or indium zinc oxide (IZO).

The metal layers 11 and 12 each have a function for blocking UV light, and the two in combination constitute a light shielding layer 14. The transparent conductive film 13 forms a transmissive layer that allows UV light to be transmitted. The metal layer 12 and the transparent conductive film 13 are both shaped similar to the metal layer 11. The surface area of the metal layer 12 is smaller than that of the metal layer 11, and the surface area of the transparent conductive film 13 is the same as that of the metal layer 11.

The wiring unit 10 shown in FIG. 17 is a longitudinal rectangle, and in the drawing there is a coarse hatching area inside a fine hatching area. The fine hatching area represents an area where light is blocked by the metal layer 11. The coarse hatching area represents an area where light is blocked by both the metal layer 11 and the metal layer 12.

As shown in FIG. 17, when the surface area of the light shielding layer 14 coincides with the entire surface area of the wiring unit 10, the entire wiring unit 10 constitutes a light shielding section through which light does not pass. Since the entire wiring unit 10 constitutes a light shielding section, a large percentage of the UV-curable ACF remains uncured, and this gives rise to the problems described above.

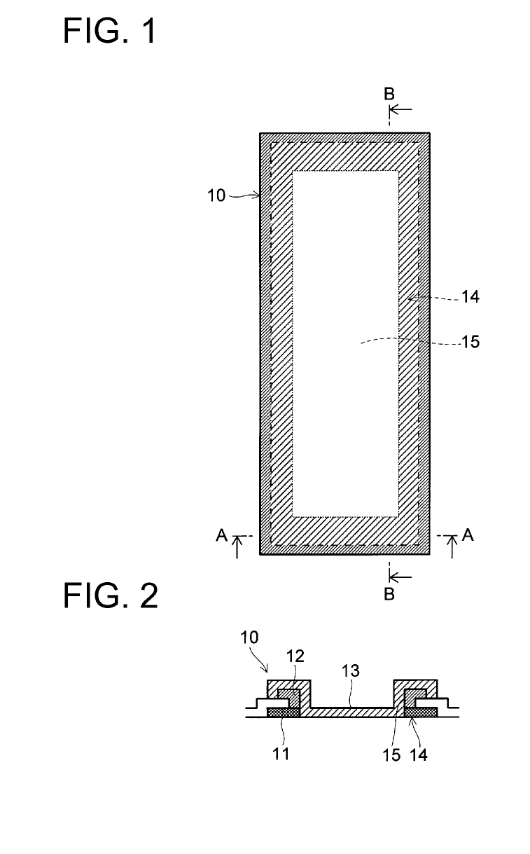

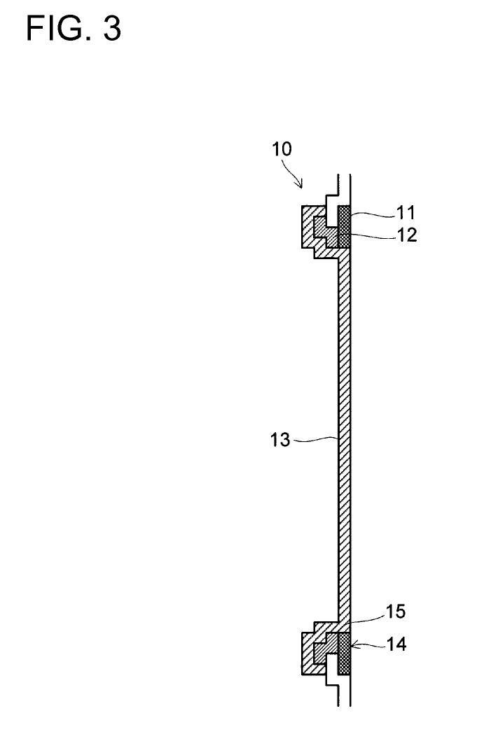

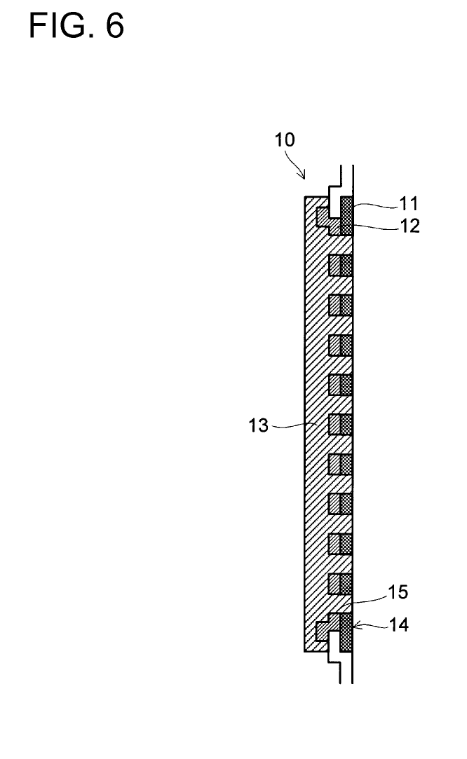

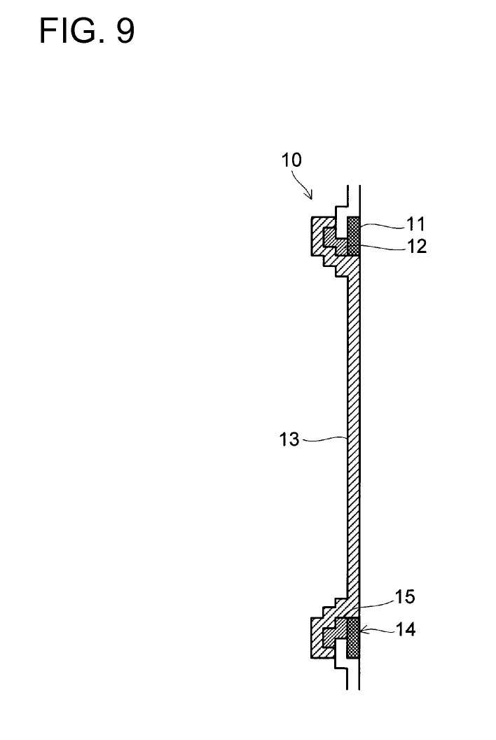

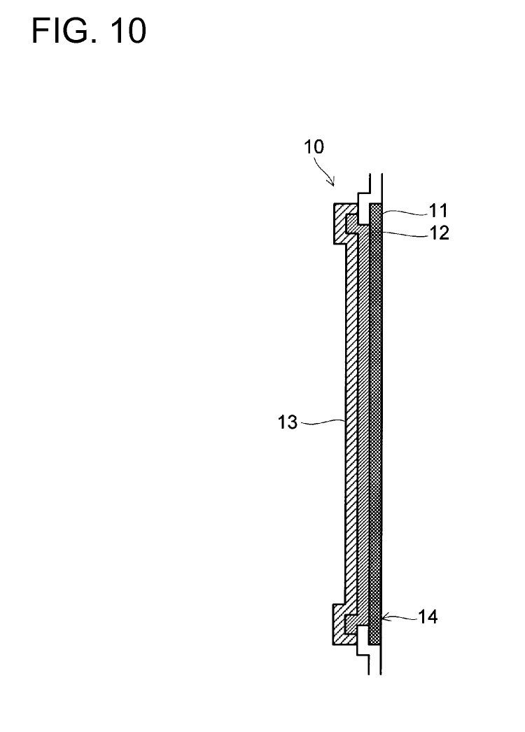

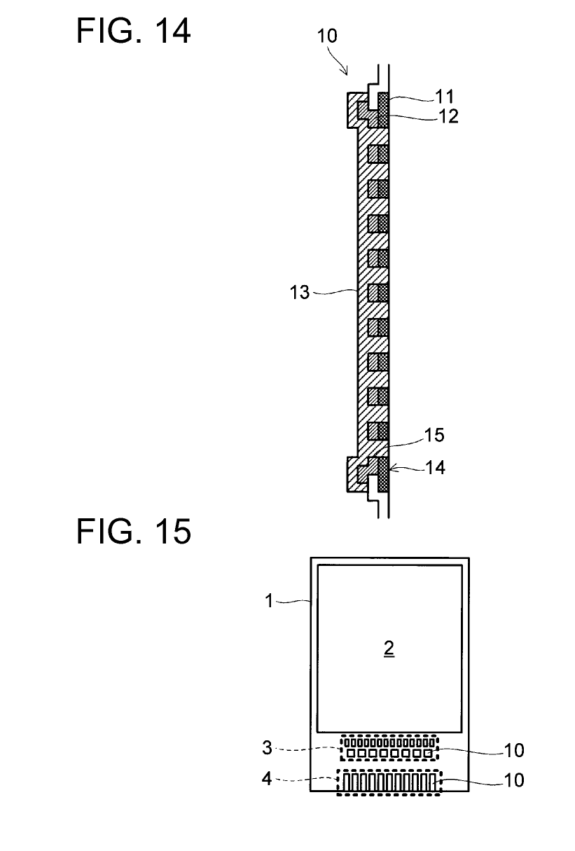

The embodiments of the present invention shown in FIGS. 1 to 14 solve for the aforementioned problems. The embodiment of FIGS. 1 to 4 will be explained below. Furthermore, the reference characters used in the explanation of the prior art will be used as-is for constituent elements that share functions in common with the prior art, and explanations thereof will be omitted.

### Embodiment 1

FIGS. 1 to 3 show Embodiment 1. The point that differs from the prior art is the fact that an opening 15 has been formed in the light shielding layer 14. It is assumed here that one opening 15 is arranged relative to one light shielding layer 14. The shape of the opening 15 is similar to the shape of the light shielding layer 14 (which is rectangular here).

The opening 15 is filled in with the transparent conductive film 13. In FIG. 1, the white space in the center of the hatching areas indicates the opening 15 that has been filled in with the transparent conductive film 13.

As described above, the transparent conductive film 13 is a transmissive layer, and does not block UV light. Therefore, when UV light is irradiated from the back side of the TFT glass substrate 1, the UV light is directly irradiated through the opening 15 onto the UV-curable ACF positioned between the wiring unit 10 and the driver IC 5, or onto the UV-curable ACF positioned between the wiring unit 10 and the FPC 6. The light shielding layer 14 outside of the opening 15 blocks the UV light, but the percentage of uncured UV-curable ACF resulting therefrom is greatly reduced.

In Embodiment 1, because one opening 15 that is shaped similar to the light shielding layer 14 is provided relative to one light shielding layer 14, the opening 15 is easy to form.

### Embodiment 2

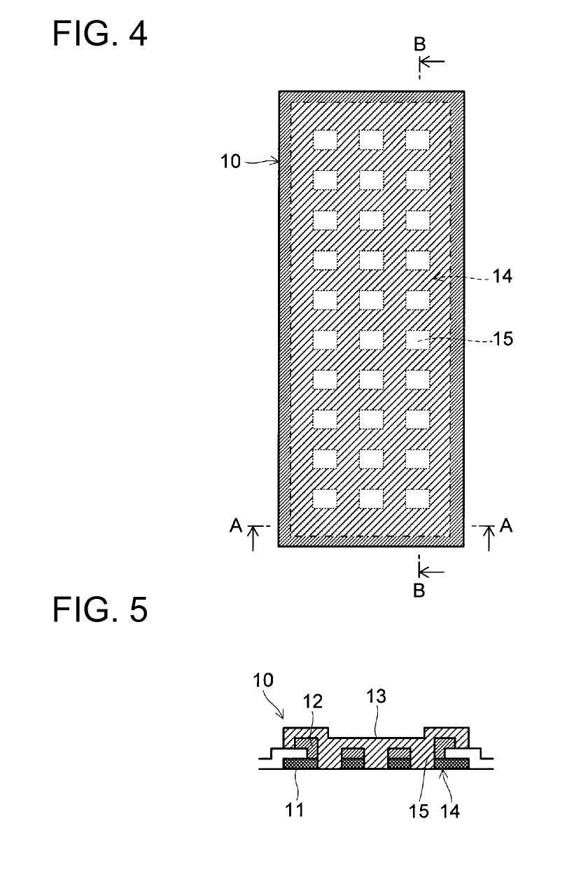

FIGS. 4 to 6 show Embodiment 2. In Embodiment 2, a plurality of openings 15 is dispersedly arranged relative to one light shielding layer 14. In FIG. 4, the white spaces within the hatching area indicate the openings 15 that have been filled in with the transparent conductive film 13. Each of the individual openings 15 is a square, and these openings 15 are arranged in a matrix. The matrix of openings 15 is given as 10 rows by three columns in FIG. 4, but this is merely illustrative and does not limit the invention.

The opening 15 may be a shape other than a square, for example, a rectangle, a circle, or some other shape. The dispersed arrangement pattern of the openings 15 is not limited to a matrix. A random arrangement may be used. The mode may be such that openings 15 of different shapes and sizes are arranged in random locations and at random angles.

In Embodiment 2, the dispersed arrangement of a plurality of openings 15 rather than the formation of only one opening 15 with a large surface area makes it possible to ensure the strength and the current carrying capacity of the light shielding layer 14 while also enabling UV light to be directly irradiated onto the UV-curable ACF.

### Embodiment 3

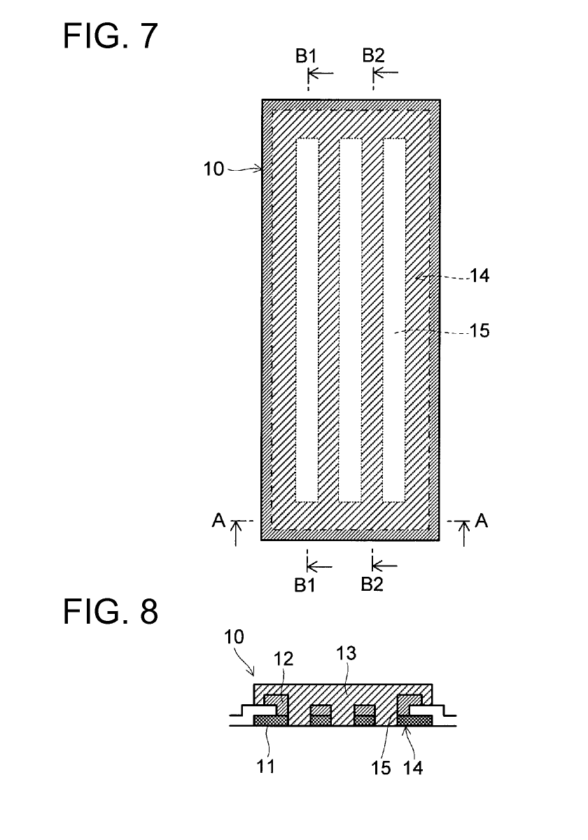

FIGS. 7 to 10 show Embodiment 3. In Embodiment 3 as well, a plurality of openings 15 is dispersedly arranged relative to one light shielding layer 14. In FIG. 7, the white spaces within the hatching area indicate the openings 15 that are filled in with the transparent conductive film 13. Each individual opening 15 has a shape, a rectangle here, that has a longitudinal direction. The plurality of openings 15 is parallelly arranged in such a way that the longitudinal direction of the openings themselves coincides with the longitudinal direction of the light shielding layer 14. The number of openings 15 is given as three in FIG. 7, but this is merely illustrative and does not limit the invention.

The longitudinal direction of the openings 15 does not necessarily have to coincide with the longitudinal direction of the light shielding layer 14. The longitudinal direction of the openings 15 may be diagonal relative to the longitudinal direction of the light shielding layer 14. The plurality of openings 15 may also form a variety of angles. As long as the openings 15 are shapes that have a longitudinal direction, the shape can be something other than the rectangle shown in FIG. 7, such as an oval shape, an elliptical shape, or a diamond shape. The size of the openings 15 may vary.

In Embodiment 3, the dispersed arrangement of a plurality of openings 15 in such a way that the plurality of openings 15 is parallelly arranged to cause the longitudinal direction of the openings themselves to coincide with the longitudinal direction of the light shielding layer 14 rather than the formation of only one opening 15 having a large surface area makes it possible to ensure the strength and the current carrying capacity of the light shielding layer 14 while also enabling UV light to be directly irradiated onto the UV-curable ACF.

### Embodiment 4

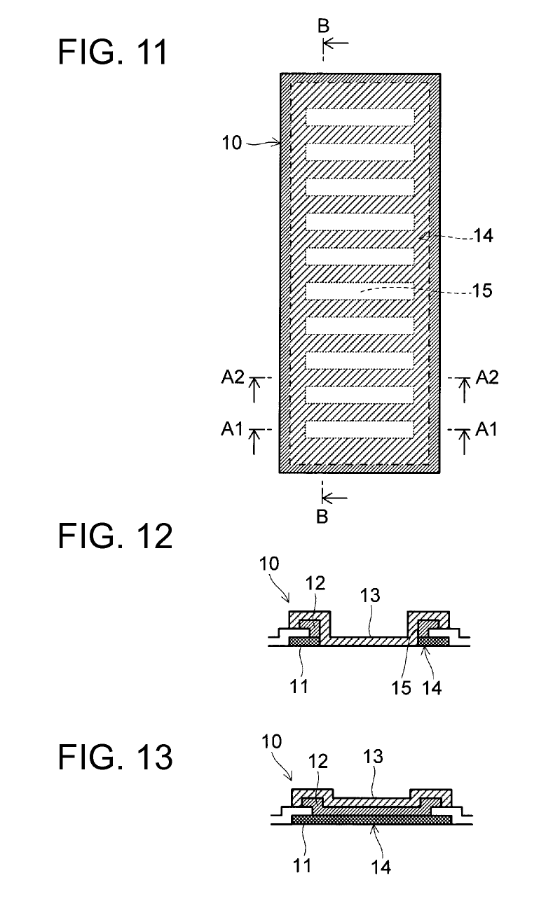

FIGS. 11 to 14 show Embodiment 4. In Embodiment 4 as well, a plurality of openings 15 is dispersedly arranged relative to one light shielding layer. In FIG. 11, the white spaces within the hatching area indicate the openings 15 that are filled in with the transparent conductive film 13. Each individual opening 15 has a shape, a rectangle here, that has a longitudinal direction. The plurality of openings 15 is parallelly arranged in such a way that the longitudinal direction of the openings themselves intersects at right angles with the longitudinal direction of the light shielding layer 14. The number of openings 15 is given as 10 in FIG. 11, but this is merely illustrative and does not limit the invention. Furthermore, the longitudinal direction of the openings 15 intersects at right angles with the longitudinal direction of the light shielding layer 14, but this is merely illustrative, and the longitudinal direction of the openings 15 may intersect with the longitudinal direction of the light shielding layer 14 at an angle other than a right angle.

In the same manner as Embodiment 3, as long as the openings 15 are shapes that have a longitudinal direction, the shape can be something other than the rectangle shown in FIG. 11, such as an oval shape, an elliptical shape, or a diamond shape. The size of the openings 15 may vary.

In Embodiment 4, the dispersed arrangement of a plurality of openings 15 in such a way that the plurality of openings 15 is parallelly arranged to cause the longitudinal direction of the openings themselves to intersect at right angles with the longitudinal direction of the light shielding layer 14 rather than the formation of only one opening 15 having a large surface area makes it possible to ensure the strength and the current carrying capacity of the light shielding layer 14 while also enabling UV light to be directly irradiated onto the UV-curable ACF.

The embodiments of the present invention have been explained above, but the scope of the present invention is not limited thereto. The present invention can be implemented by making various changes without departing from the gist of the invention.

### INDUSTRIAL APPLICABILITY

The present invention can be used widely in display panels and ordinary circuit boards.

### DESCRIPTION OF REFERENCE CHARACTERS

1 TFT glass substrate

2 display section

3 COG mounting section

4 FOG mounting section

5 driver IC

6 FPC

10 wiring unit

11, 12 metal layer

13 transparent conductive film

14 light shielding layer

15 opening

1. A component securing structure, comprising:
a substrate that transmits ultraviolet light and that has a wiring unit formed thereon, said substrate electrically connecting a component thereon to said wiring unit and securing said component to the substrate with an ultraviolet-curable a anisotropic conductive film, said wiring unit of the substrate including a light shielding layer,
wherein an opening for transmitting ultraviolet light is formed in said light shielding layer of said wiring unit.

2. The component securing structure according to claim 1, wherein said opening in said light shielding layer has a shape similar to that of the light shielding layer.

3. The component securing structure according to claim 1, wherein a plurality of said openings are dispersed in said light shielding layer.

4. The component securing structure according to claim 3, wherein said plurality of openings are arranged in a matrix.

5. The component securing structure according to claim 2, wherein said light shielding layer and said opening are shapes each having a longitudinal direction, and said opening is parallelly arranged in such a way that the longitudinal direction of the opening coincides with the longitudinal direction of said light shielding layer.

6. The component securing structure according to claim 2, wherein said light shielding layer and said opening are shapes each having a longitudinal direction, and said opening is parallelly arranged in such a way that the longitudinal direction of the opening intersects with the longitudinal direction of said light shielding layer.

7. A circuit board, comprising:
the component securing structure according to claim 1.

8. A display panel, comprising:
the circuit board according to claim 7.
